(19) United States
(12) Patent Application Publication
(10) Pub. No.: US 2024/0021585 A1
(43) Pub. Date: Jan. 18, 2024

(54) SEMICONDUCTOR DEVICE

(71) Applicant: SUMITOMO ELECTRIC INDUSTRIES, LTD., Osaka (JP)

(72) Inventor: Tatsushi KANEDA, Osaka (JP)

(21) Appl. No.: 18/043,782

(22) PCT Filed: Apr. 28, 2021
(86) PCT No.: PCT/JP2021/017069

§ 371 Date: Mar. 2, 2023

(30) Foreign Application Priority Data
Sep. 18, 2020 (JP) 2020-157444

(51) Int. Cl. H01L 25/07; H01L 23/00; H01L 23/538

(52) U.S. Cl. CPC H01L 25/072; H01L 24/48; H01L 23/5386; H01L 2224/48225

(57) ABSTRACT

A semiconductor device includes a plurality of transistors electrically connected to each other in parallel, the plurality of transistors respectively including first electrodes, a diode electrically connected in parallel to the plurality of transistors, the diode including an anode electrode, a first conductive pattern, a second conductive pattern electrically connected to the first conductive pattern, a plurality of first connection members directly connecting the first electrodes of the plurality of transistors to the first conductive pattern, respectively, and a second connection member connecting the anode electrode to the second conductive pattern. Each of the first electrodes is a source electrode or an emitter electrode. The plurality of transistors are arranged adjacent to each other.

### TECHNICAL FIELD

The present disclosure relates to a semiconductor device.

This application is based on and claims priority to Japanese Patent Application No. 2020-157444 filed on Sep. 18, 2020, the entire contents of which are incorporated herein by reference.

### BACKGROUND ART

As a semiconductor device used in a power module, a semiconductor device, in which a source electrode or an emitter electrode of a transistor and an anode electrode of a diode are connected to each other, is proposed.

### RELATED ART DOCUMENTS

### Patent Documents

[Patent Document 1] Japanese Unexamined Patent Application Publication No. 2015-154079
[Patent Document 2] Japanese Unexamined Patent Application Publication No. 2019-71490
[Patent Document 3] U.S. Patent Application Publication No. 2017/0125322

### SUMMARY OF THE INVENTION

A semiconductor device of the present disclosure includes a plurality of transistors electrically connected to each other in parallel, the plurality of transistors respectively including first electrodes, a diode electrically connected in parallel to the plurality of transistors, the diode including an anode electrode, a first conductive pattern, a second conductive pattern electrically connected to the first conductive pattern, a plurality of first connection members directly connecting the first electrodes of the plurality of transistors to the first conductive pattern, respectively, and a second connection member connecting the anode electrode to the second conductive pattern. Each of the first electrodes is a source electrode or an emitter electrode. The plurality of transistors are arranged adjacent to each other.

### BRIEF DESCRIPTION OF THE DRAWINGS

FIG. 1 is a perspective view illustrating a semiconductor device according to a first embodiment.

FIG. 2 is a top view illustrating the semiconductor device according to the first embodiment.

FIG. 3 is a cross-sectional view illustrating a relationship between a heat dissipation plate, a first insulating substrate, and a second insulating substrate in the semiconductor device according to the first embodiment.

FIG. 4 is a cross-sectional view illustrating a first transistor.

FIG. 5 is a cross-sectional view illustrating a first diode.

FIG. 6 is a cross-sectional view illustrating a second transistor.

FIG. 7 is a cross-sectional view illustrating a second diode.

FIG. 8 is a circuit diagram illustrating the semiconductor device according to the first embodiment.

FIG. 9 is a schematic diagram (1) illustrating an operation of the semiconductor device according to the first embodiment.

FIG. 10 is a schematic diagram (2) illustrating the operation of the semiconductor device according to the first embodiment.

FIG. 11 is a schematic view (3) illustrating the operation of the semiconductor device according to the first embodiment.

FIG. 12 is a schematic view (4) illustrating the operation of the semiconductor device according to the first embodiment.

FIG. 13 is a cross-sectional view illustrating a modified example of the heat dissipation plate.

FIG. 14 is a schematic view illustrating a configuration of a first insulating substrate and a second insulating substrate in a semiconductor device according to a second embodiment.

FIG. 15 is a top view illustrating a semiconductor device according to a third embodiment.

FIG. 16 is a cross-sectional view illustrating a relationship between a heat dissipation plate and an insulating substrate in the semiconductor device according to the third embodiment.

FIG. 17 is a cross-sectional view illustrating a relationship between a heat dissipation plate and a conductive layer in a modified example of the third embodiment.

### EMBODIMENT FOR CARRYING OUT THE INVENTION

### Problems to be Solved by the Present Disclosure

It is desired to achieve more stable operations of multiple transistors connected in parallel.

It is an object of the present disclosure to provide a semiconductor device that can achieve more stable operations of multiple transistors connected in parallel.

### Effects of the Present Disclosure

According to the present disclosure, more stable operations of multiple transistors connected in parallel can be achieved.

Embodiments will be described below.

### Description of the Embodiments of the Present Disclosure

First, the embodiments of the present disclosure will be listed and described. In the following description, identical or corresponding elements are referenced by the same reference signs and description thereof will not be repeated.

[1] A semiconductor device according to one aspect of the present disclosure includes a plurality of transistors electrically connected in parallel to each other and respectively including first electrodes, a diode electrically connected in parallel to the plurality of transistors and including an anode electrode, a first conductive pattern, a second conductive pattern electrically connected to the first conductive pattern, a plurality of first connection members directly connecting the first electrodes of the plurality of transistors to the first conductive pattern, respectively, and a second connection member connecting the anode electrode to the second conductive pattern. Each of the first electrodes is a source electrode or an emitter electrode. The plurality of transistors are arranged adjacent to each other.

The plurality of transistors are arranged adjacent to each other. The first electrode (the source electrode or the emitter electrode) and the first conductive pattern are directly connected by the first connection member, the anode electrode and the second conductive pattern are connected by the second connection member, and the first conductive pattern and the second conductive pattern are electrically connected. Thus, the inductance of the power loop of each of the plurality of transistors can be reduced, and the variation in the inductance of the power loop between the plurality of transistors can be suppressed. Therefore, more stable operations of the plurality of transistors connected in parallel can be achieved and suppressed.

[2] A semiconductor device according to another aspect of the present disclosure includes a plurality of transistors electrically connected in parallel to each other and respectively including first electrodes, a diode electrically connected in parallel to the plurality of transistors and including an anode electrode, a third conductive pattern, a plurality of first connection members directly connecting the first electrodes of the plurality of transistors to the third conductive pattern, respectively, and a second connection member connecting the anode electrode to the third conductive pattern. Each of the first electrodes is a source electrode or an emitter electrode. The plurality of transistors are arranged adjacent to each other.

The plurality of transistors are arranged adjacent to each other. The first electrode (the source electrode or the emitter electrode) and the third conductive pattern are directly connected by the first connection member, and the anode electrode and the third conductive pattern are connected by the second connection member. Thus, the inductance of the power loop of each of the plurality of transistors can be reduced, and the variation in the inductance of the power loop between the plurality of transistors can be suppressed. Therefore, more stable operations of the plurality of transistors connected in parallel can be achieved.

[3] In [1] or [2], the plurality of transistors may be aggregated in a first region having a rectangular shape. In this case, the variation in inductance of the power loop is easily suppressed.

[4] in [1] to [3], the plurality of transistors may be arranged side by side in a first direction. In this case, the variation in the inductance of the power loop is easily suppressed by aggregating the plurality of transistors.

[5] In [1] to [4], the second connection member may be independent of the plurality of first connection members. In this case, the variation in the inductance of the power loop is easily suppressed.

[6] in [1] to [5], the diode may not be disposed between transistors adjacent to each other among the plurality of transistors. In this case, the variation in the inductance of the power loop is easily suppressed.

[7] In [1] to [6], each of the transistors may be a field effect transistor formed using silicon carbide. In this case, an excellent breakdown voltage is obtained in the transistor.

[8] in [1] to [7], the diode may be a Schottky barrier diode formed using silicon carbide. In this case, an excellent breakdown voltage is obtained in the diode.

[9] In [1] to [8], a case that accommodates the plurality of transistors and the diode, and a control terminal connected to control electrodes of the plurality of transistors and attached to the case are included. The case may include a pair of side walls opposite to each other and a pair of end walls connecting both ends of the side walls, and the control terminal may be provided on a wall positioned closest to the plurality of transistors among the side walls and the end walls. In this case, the plurality of transistors can be aggregated in the vicinity of the control terminal. Thus, the difference in the inductance of the gate loop between the plurality of transistors is easily reduced. Therefore, more stable operations of the plurality of transistors connected in parallel is easily achieved.

### Details of the Embodiments of the Present Disclosure

In the following, the embodiments of the present disclosure will be described in detail, but the embodiments are not limited thereto. Here, in the present specification and the drawings, constituent elements having substantially the same functional configuration are referenced by the same reference signs and description thereof may be omitted.

### First Embodiment

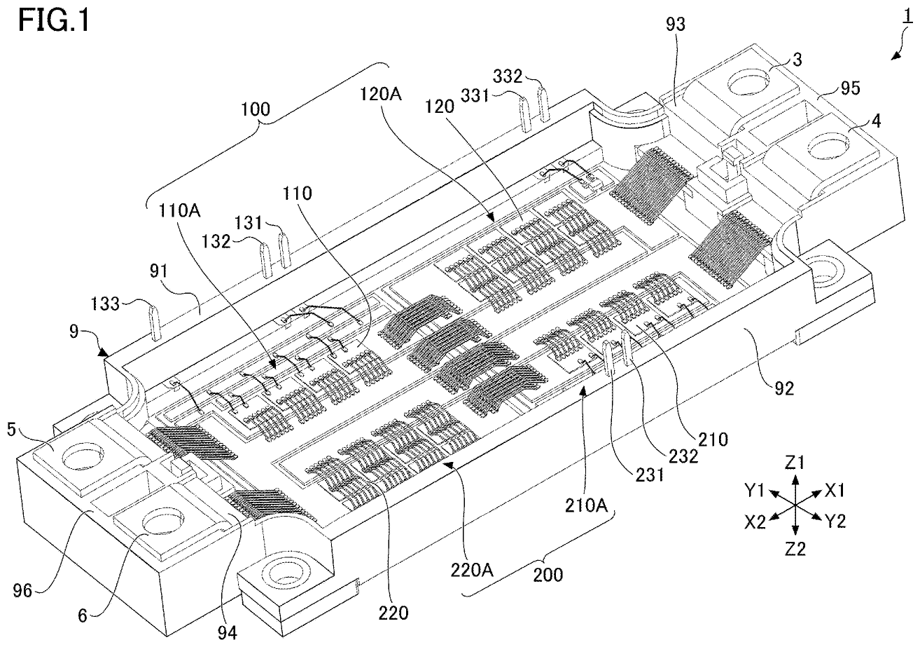

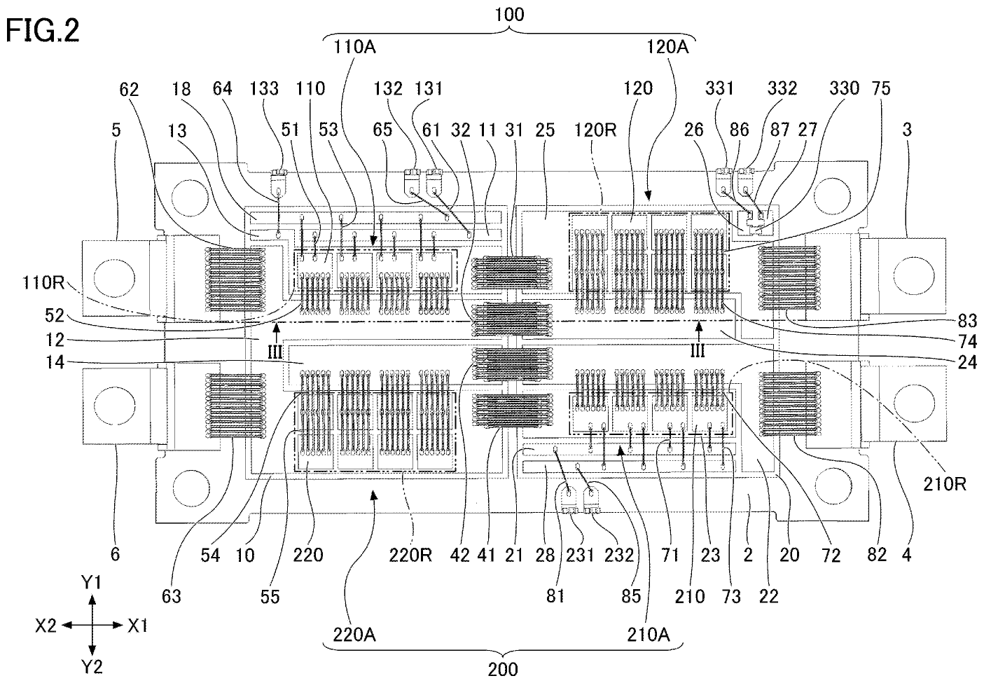

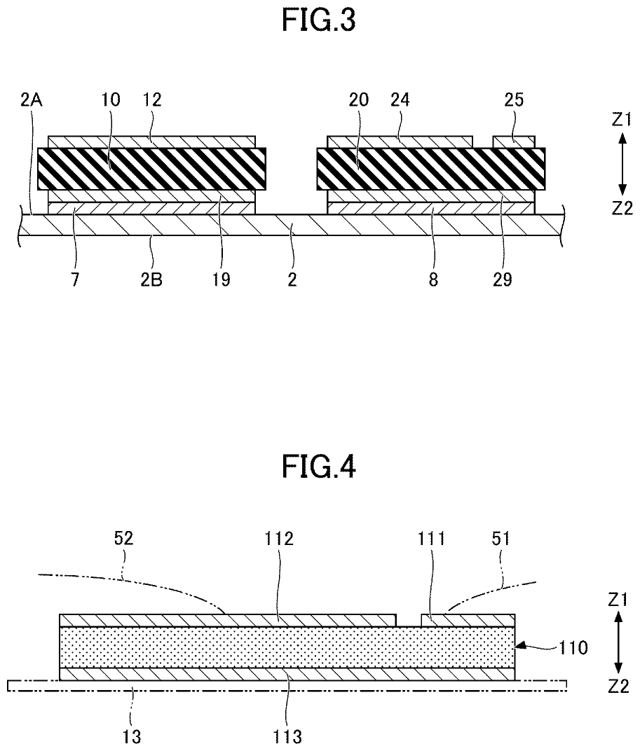

First, a first embodiment will be described. FIG. 1 is a perspective view illustrating a semiconductor device according to the first embodiment. FIG. 2 is a top view illustrating the semiconductor device according to the first embodiment. Here, in FIG. 2, the drawing is illustrated with seeing through the case. FIG. 3 is a cross-sectional view illustrating a relationship between a heat dissipation plate, a first insulating substrate, and a second insulating substrate in the semiconductor device according to the first embodiment. FIG. 3 corresponds to a cross-sectional view taken along line III-III in FIG. 2.

The semiconductor device 1 according to the first embodiment mainly includes a heat dissipation plate 2, a case 9, a P terminal 3, an N terminal 4, a first O terminal 5, and a second O terminal 6. The P terminal 3 is a power supply terminal on the positive electrode side, the N terminal 4 is a power supply terminal on the negative electrode side, and the first O terminal 5 and the second O terminal 6 are output terminals. The P terminal 3, the N terminal 4, and the first O terminal 5 and the second O terminal 6 are assembled in the case 9. A first gate terminal 131, a first sense source terminal 132, a sense drain terminal 133, a second gate terminal 231, a second sense source terminal 232, a first thermistor terminal 331, and a second thermistor terminal 332 are further assembled in the case 9.

In the present disclosure, the X1-X2 direction, the Y1-Y2 direction, and the Z1-Z2 direction are directions orthogonal to each other. A plane including the X1-X2 direction and the Y1-Y2 direction is defined as the XY plane, a plane including the Y1-Y2 direction and the Z1-Z2 direction is defined as the YZ plane, and a plane including the Z1-Z2 direction and the X1-X2 direction is defined as the ZX plane. For convenience, the Z1 direction is defined as an upward direction, and the Z2 direction is defined as a downward direction. Additionally, in the present disclosure, plan view refers to viewing an object from the Z1 side. The X1-X2 direction is a direction along the long side of the heat dissipation plate 2 and the case 9 that have rectangular shapes in plan view, the Y1-Y2 direction is a direction along the short side of the heat dissipation plate 2 and the case 9, and the Z1-Z2 direction is a direction along the normal to the heat dissipation plate 2 and the case 9.

The heat dissipation plate 2 is, for example, a plate body having a uniform thickness and a rectangular shape in plan view. The heat dissipation plate 2 has a first main surface 2A and a second main surface 2B opposite to the first main surface 2A. The material of the heat dissipation plate 2 is metal, which is a material having a high thermal conductivity, such as copper (Cu), a copper alloy, aluminum (Al), or the like. The heat dissipation plate 2 is fixed to a cooler or the like by using a thermal interface material (TIM) or the like.

The case 9 is formed in a frame shape in plan view, for example, and the outer shape of the case 9 is substantially the same as the outer shape of the heat dissipation plate 2. The material of the case 9 is an insulator such as resin or the like. The case 9 has a pair of side walls 91 and 92 facing each other, and a pair of end walls 93 and 94 connecting both ends of the side walls 91 and 92. The side walls 91 and 92 are arranged in parallel to the ZX plane, and the end walls 93 and 94 are arranged in parallel to the YZ plane. The side wall 92 is disposed on the Y2 side from the side wall 91, and the end wall 94 is disposed on the X2 side from the end wall 93. The case 9 includes a terminal block 95 projecting from the end wall 93 in the X1 direction and a terminal block 96 projecting from the end wall 94 in the X2 direction.

The P terminal 3 and the N terminal 4 are arranged on the upper surface (the surface on the Z1 side) of the terminal block 95, and the first O terminal 5 and the second O terminal 6 are arranged on the upper surface (the surface on the Z1 side) of the terminal block 96. For example, the N terminal 4 is disposed on the Y2 side from the P terminal 3, and the second O terminal 6 is disposed on the Y2 side from the first O terminal 5. The P terminal 3, the N terminal 4, the first O terminal 5, and the second O terminal 6 are formed of metal plates. One end of each of the P terminal 3 and the N terminal 4 is exposed on the X2 side of the end wall 93, and the other end of each of the P terminal 3 and the N terminal 4 is drawn to the upper surface of the terminal block 95. One end of each of the first O terminal 5 and the second O terminal 6 is exposed on the X1 side of the end wall 94, and the other end of each of the first O terminal 5 and the second O terminal 6 is drawn to the upper surface of the terminal block 96.

The first gate terminal 131, the first sense source terminal 132, the sense drain terminal 133, the first thermistor terminal 331, and the second thermistor terminal 332 are attached to the side wall 91. One end of each of the first gate terminal 131, the first sense source terminal 132, the sense drain terminal 133, the first thermistor terminal 331, and the second thermistor terminal 332 is exposed on the Y2 side of the side wall 91, and the other end thereof projects from the upper surface (the surface on the Z1 side) of the side wall 91 to the outside (the Z1 side) of the case 9. The sense drain terminal 133 is disposed in the vicinity of the end of the side wall 91 on the X2 side. The first thermistor terminal 331 and the second thermistor terminal 332 are disposed in the vicinity of the end of the side wall 91 on the X1 side. For example, the second thermistor terminal 332 is disposed on the X1 side from the first thermistor terminal 331. The first gate terminal 131 and the first sense source terminal 132 are disposed in the vicinity of the center of the side wall 91 in the X1-X2 direction and on the X2 side from the center in the X1-X2 direction. For example, the first sense source terminal 132 is disposed on the X2 side from the first gate terminal 131.

The second gate terminal 231 and the second sense source terminal 232 are attached to the side wall 92. One end of each of the second gate terminal 231 and the second sense source terminal 232 is exposed on the Y1 side of the side wall 92, and the other end thereof projects from the upper surface (the surface on the Z1 side) of the side wall 92 to the outside (the Z1 side) of the case 9. The second crate terminal 231 and the second sense source terminal 232 are disposed in the vicinity of the center of the side wall 92 in the X1-X2 direction and on the X1 side from the center in the X1-X2 direction. For example, the second sense source terminal 232 is disposed on the X1 side from the second gate terminal 231.

A first insulating substrate 10 and a second insulating substrate 20 are disposed on the Z1 side of the heat dissipation plate 2. That is, the first insulating substrate 10 and the second insulating substrate 20 are disposed on the first main surface 2A of the heat dissipation plate 2. For example, the second insulating substrate 20 is disposed on the X1 side from the first insulating substrate 10.

The first insulating substrate 10 includes conductive layers 11, 12, 13, 14, and 18 on the Z1 side surface, and a conductive layer 19 on the Z2 side surface. The conductive layer 19 is bonded to the heat dissipation plate 2 by a bonding material 7 such as solder or the like. Multiple first transistors 110, for example, four first transistors 110 are implemented on the conductive layer 13. The four first transistors 110 are arranged in the X1-X2 direction. The four first transistors 110 constitute a first transistor group 110A. Multiple second diodes 220, for example, eight second diodes 220 are implemented on the conductive layer 12. The eight second diodes 220 are arranged in two rows, four each in the X1-X2 direction. The eight second diodes 220 constitute a second diode group 220A.

The four first transistors 110 are arranged adjacent to each other in a first transistor aggregation region 110R having a rectangular shape in plan view. That is, the four first transistors 110 are aggregated in the first transistor aggregation region 110R. The eight second diodes 220 are arranged adjacent to each other in a second diode aggregation region 220R having a rectangular shape in plan view. That is, the eight second diodes 220 are aggregated in the second diode aggregation region 220R. The first transistor aggregation region 110R is an example of the first region. The X1-X2 direction is an example of the first direction.

The second insulating substrate 20 includes conductive layers 21, 22, 23, 24, 25, 26, 27, and 28 on the Z1 side surface, and a conductive layer 29 on the Z2 side surface. The conductive layer 29 is bonded to the heat dissipation plate 2 by a bonding material 8 such as solder or the like. Multiple second transistors 210, for example, four second transistors 210 are implemented on the conductive layer 23. The four second transistors 210 are arranged in the X1-X2 direction. The four second transistors 210 constitute a second transistor group 210A. Multiple first diodes 120, for example, eight first diodes 120 are implemented on the conductive layer 25. The eight first diodes 120 are arranged in two rows, four each in the X1-X2 direction. The eight first diodes 120 constitute a first diode group 120A.

The four second transistors 210 are arranged adjacent to each other in a second transistor aggregation region 210R having a rectangular shape in plan view. That is, the four second transistors 210 are aggregated in the second transistor aggregation region 210R. The eight first diodes 120 are arranged adjacent to each other in a first diode aggregation region 120R having a rectangular shape in plan view. That is, the eight first diodes 120 are aggregated in the first diode aggregation region 120R. The second transistor aggregation region 210R is another example of the first region.

In plan view, the first diode aggregation region 120R is separated from the first transistor aggregation region 110R, and the first transistor aggregation region 110R and the first diode aggregation region 120R do not have a region overlapping each other. The first diode 120 is not disposed between the first transistors 110 adjacent to each other. In plan view, the second transistor aggregation region 210R is separated from the second diode aggregation region 220R, and the second transistor aggregation region 210R and the second diode aggregation region 220R do not have a region overlapping each other. The second diode 220 is not disposed between the second transistors 210 adjacent to each other.

A combination of the conductive layer 12, the conductive layer 24, the wire 52, and the wires 74 and 75 is an example of a combination of the first conductive pattern, the second conductive pattern, the first connection member, and the second connection member. A combination of the conductive layer 22, the conductive layer 14, the wire 72, and the wires 54 and 55 is another example of the combination of the first conductive pattern, the second conductive pattern, the first connection member, and the second connection member.

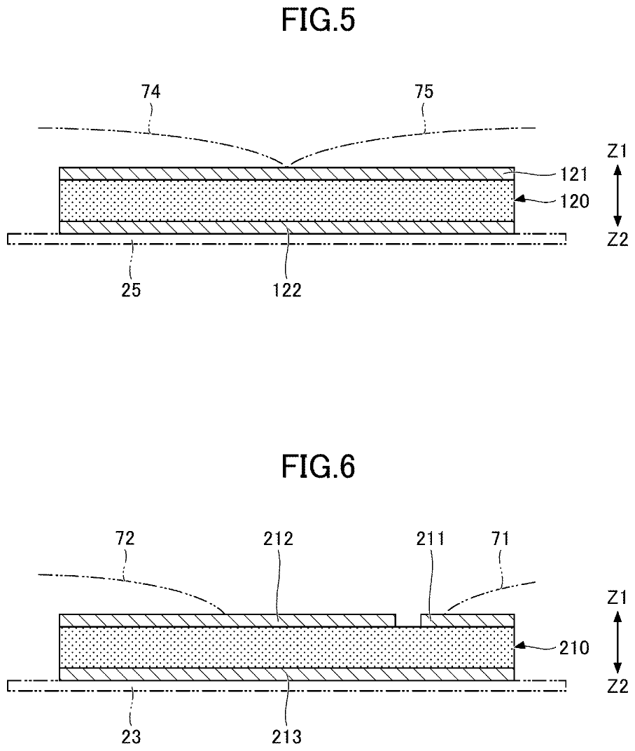

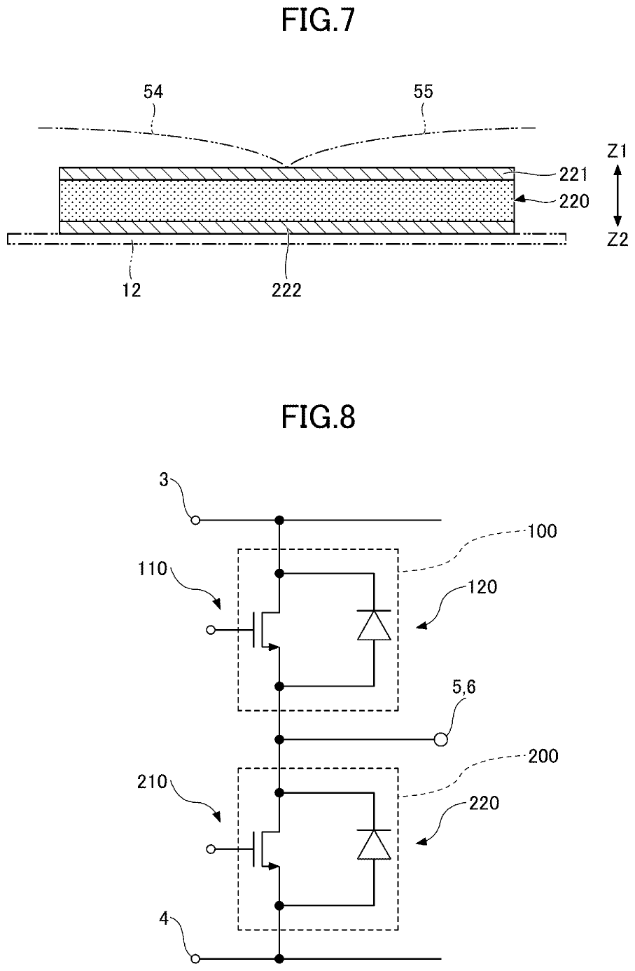

Here, the first transistor 110, the first diode 120, the second transistor 210, and the second diode 220 will be described. FIG. 4 is a cross-sectional view illustrating the first transistor. FIG. 5 is a cross-sectional view illustrating the first diode. FIG. 6 is a cross-sectional view illustrating the second transistor. FIG. 7 is a cross-sectional view illustrating the second diode.

As illustrated in FIG. 4, the first transistor 110 includes a first gate electrode 111, a first source electrode 112, and a first drain electrode 113. The first gate electrode 111 and the first source electrode 112 are disposed on the Z1 side main surface of the first transistor 110, and the first drain electrode 113 is disposed on the Z2 side main surface of the first transistor 110. The first drain electrode 113 is bonded to the conductive layer 13 by a bonding material (not illustrated) such as solder or the like. The first source electrode 112 is an example of the first electrode.

As illustrated in FIG. 5, the first diode 120 includes a first anode electrode 121 and a first cathode electrode 122. The first anode electrode 121 is disposed on the Z1 side main surface of the first diode 120, and the first cathode electrode 122 is disposed on the Z2 side main surface of the first diode 120. The first cathode electrode 122 is bonded to the conductive layer 25 by a bonding material (not illustrated) such as solder or the like.

As illustrated in FIG. 6, the second transistor 210 includes a second gate electrode 211, a second source electrode 212, and a second drain electrode 213. The second gate electrode 211 and the second source electrode 212 are disposed on the Z1 side main surface the second transistor 210, and the second drain electrode 213 is disposed on the Z2 side main surface of the second transistor 210. The second drain electrode 213 is bonded to the conductive layer 23 by a bonding material (not illustrated) such as solder or the like. The second source electrode 212 is another example of the first electrode.

As illustrated in FIG. 7, the second diode 220 includes a second anode electrode 221 and a second cathode electrode 222. The second anode electrode 221 is disposed on the Z1 side main surface of the second diode 220, and the second cathode electrode 222 is disposed on the Z2 side main surface of the second diode 220. The second cathode electrode 222 is bonded to the conductive layer 12 by a bonding material (not illustrated) such as solder or the like.

The semiconductor device 1 includes multiple wires 31, multiple wires 32, multiple wires 41, and multiple wires 42. The wires 31 connect the conductive layer 13 provided on the first insulating substrate 10 to the conductive layer 25 provided on the second insulating substrate 20. The wires 32 connect the conductive layer 12 provided on the first insulating substrate 10 to the conductive layer 24 provided on the second insulating substrate 20. The wires 41 connect the conductive layer 12 provided on the first insulating substrate 10 to the conductive layer 23 provided on the second insulating substrate 20. The wires 42 connect the conductive layer 14 provided on the first insulating substrate 10 to the conductive layer 22 provided on the second insulating substrate 20.

The semiconductor device 1 includes multiple wires 51, multiple wires 52, multiple wires 53, multiple wires 54, and multiple wires 55. The wire 51 connects the first gate electrode 111 provided in each of the four first transistors 110 to the conductive layer 11 provided on the first insulating substrate 10. The wire 52 connects the first source electrode 112 provided in each of the four first transistors 110 to the conductive layer 12 provided on the first insulating substrate 10. The wire 53 connects a first sense source electrode (not illustrated) provided in each of the four first transistors 110 to the conductive layer 18 provided on the first insulating substrate 10. The wire 54 connects the second anode electrode 221 provided in each of the four second diodes 220 disposed on the Y1 side among the eight second diodes 220 to the conductive layer 14 provided on the first insulating substrate 10. The wire 55 connects the second anode electrode 221 provided in each of the four second diodes 220 disposed on the Y1 side among the eight second diodes 220 to the second anode electrode 221 provided in each of the four second diodes 220 disposed on the Y2 side.

The semiconductor device 1 includes a wire 61, multiple wires 62, multiple wires 63, a wire 64, and a wire 65. The wire 61 connects the conductive layer 11 provided on the first insulating substrate 10 to the first gate terminal 131. The wires 62 connect the conductive layer 12 provided on the first insulating substrate 10 to the first O terminal 5. The wires 63 connect the conductive layer 12 provided on the first insulating substrate 10 to the second O terminal 6. The wire 64 connects the conductive layer 13 provided on the first insulating substrate 10 to the sense drain terminal 133. The wire 65 connects the conductive layer 18 provided on the first insulating substrate 10 to the first sense source terminal 132.

The semiconductor device 1 includes multiple wires 71, multiple wires 72, multiple wires 73, multiple wires 74, and multiple wires 75. The wire 71 connects the second gate electrode 211 provided in each of the four second transistors 210 to the conductive layer 21 provided on the second insulating substrate 20. The wire 72 connects the second source electrode 212 provided in each of the four second transistors 210 to the conductive layer 22 provided on the second insulating substrate 20. The wire 73 connects the second sense source electrode (not illustrated) provided in each of the four second transistors 210 to the conductive layer 28 provided on the second insulating substrate 20. The wire 74 connects the first anode electrode 121 provided in each of the four first diodes 120 disposed on the Y2 side among the eight first diodes 120 to the conductive layer 24 provided on the second insulating substrate 20. The wire 75 connects the first anode electrode 121 provided in each of the four first diodes 120 disposed on the Y2 side among the eight first diodes 120 to the first anode electrode 121 provided in the four first diodes 120 disposed on the Y1 side.

The semiconductor device 1 includes a wire 81, multiple wires 82, multiple wires 83, a wire 85, a wire 86, and a wire 87. The wire 81 connects the conductive layer 21 provided on the second insulating substrate 20 to the second gate terminal 231. The wire 82 connects the conductive layer 22 provided on the second insulating substrate 20 to the N terminal 4. The wire 83 connects the conductive layer 25 provided on the second insulating substrate 20 to the P terminal 3. The wire 85 connects the conductive layer 28 provided on the second insulating substrate 20 to the second sense source terminal 232. The wire 86 connects the conductive layer 26 provided on the second insulating substrate 20 to the first thermistor terminal 331. The wire 87 connects the conductive layer 27 provided on the second insulating substrate 20 to the second thermistor terminal 332. The semiconductor device 1 includes a thermistor 330 connected to the conductive layer 26 and the conductive layer 27.

Here, a circuit configuration of the semiconductor device 1 according to the first embodiment will be described. FIG. 8 is a circuit diagram illustrating the semiconductor device according to the first embodiment.

The first cathode electrode 122 of the first diode 120 is connected to the P terminal 3 via the wire 83 and the conductive layer 25. Additionally, the first drain electrode 113 of the first transistor 110 is connected to the P terminal 3 via the wire 83, the conductive layer 25, the wire 31, and the conductive layer 13. The conductive layer 12 is connected to the first O terminal 5 via the wire 62 and is connected to the second O terminal 6 via the wire 63. The first source electrode 112 of the first transistor 110 is connected to the conductive layer 12 via the wire 52. Additionally, the first anode electrode 121 of the first diode is connected to the conductive layer 12 via the wire 32, the conductive layer 24, and the wires 74 and 75.

The first gate electrode 111 of the first transistor 110 is connected to the first gate terminal 131 via the wire 61, the conductive layer 11, and the wire 51. The first sense source electrode of the first transistor 110 is connected to the first sense source terminal 132 via the wire 65, the conductive layer 18, and the wire 53. The first drain electrode 113 of the first transistor 110 is connected to the sense drain terminal 133 via the wire 64 and the conductive layer 13. The first gate electrode 111 is an example of the control electrode, and the first gate terminal 131 is an example of the control terminal.

The second source electrode 212 of the second transistor 210 is connected to the N terminal 4 via the wire 82, the conductive layer 22, and the wire 72. Additionally, the second anode electrode 221 of the second diode 220 is connected to the N terminal 4 via the wire 82, the conductive layer 22, the wire 42, and the wires 54 and 55. The second cathode electrode 222 of the second transistor 210 is connected to the conductive layer 12. Additionally, the second drain electrode 213 of the second transistor 210 is connected to the conductive layer 12 via the wire 41 and the conductive layer 23.

The second gate electrode 211 of the second transistor 210 is connected to the second crate terminal 231 via the wire 81, the conductive layer 21, and the wire 71. The second sense source electrode of the second transistor 210 is connected to the second sense source terminal 232 via the wire 85, the conductive layer 28, and the wire 73. One electrode of the thermistor 330 is connected to the first thermistor terminal 331 via the wire 86 and the conductive layer 26. The other electrode of the thermistor 330 is connected to the second thermistor terminal 332 via the wire 87 and the conductive layer 27. The second gate electrode 211 is another example of the control electrode, and the second gate terminal 231 is another example of the control terminal.

As illustrated in FIG. 8, the first drain electrode 113 of the first transistor 110 and the first cathode electrode 122 of the first diode 120 are connected to the P terminal 3 in common, and the first source electrode 112 and the first anode electrode 121 are connected to the first O terminal 5 and the second O terminal 6 in common. That is, the first transistor 110 and the first diode 120 are connected in parallel between the P terminal 3; and the first O terminal 5 and the second O terminal 6. Additionally, the second drain electrode 213 of the second transistor 210 and the second cathode electrode 222 of the second diode 220 are connected to the first O terminal 5 and the second O terminal 6 in common, and the second source electrode 212 and the second anode electrode 221 are connected to the N terminal 4 in common. That is, the second transistor 210 and the second diode 220 are connected in parallel between the N terminal 4; and the first O terminal 5 and the second O terminal 6. An upper arm 100 includes the first transistor 110 (the first transistor group 110A) and the first diode 120 (the first diode group 120A). A lower arm 200 includes the second transistor 210 (the second transistor group 210A) and the second diode 220 (the second diode group 220A). The upper arm 100 and the lower arm 200 are connected in series between the P terminal 3 and the N terminal 4. The upper arm 100 is an example of a first arm, and the lower arm 200 is an example of a second arm.

The multiple first transistors 110 included in the upper arm 100 may be provided only on the first insulating substrate 10, and the multiple first diodes 120 included in the upper arm 100 may be provided only on the second insulating substrate 20. Additionally, the multiple second transistors 210 included in the lower arm 200 may be provided only on the second insulating substrate 20, and the multiple second diodes 220 included in the lower arm 200 may be provided only on the first insulating substrate 10.

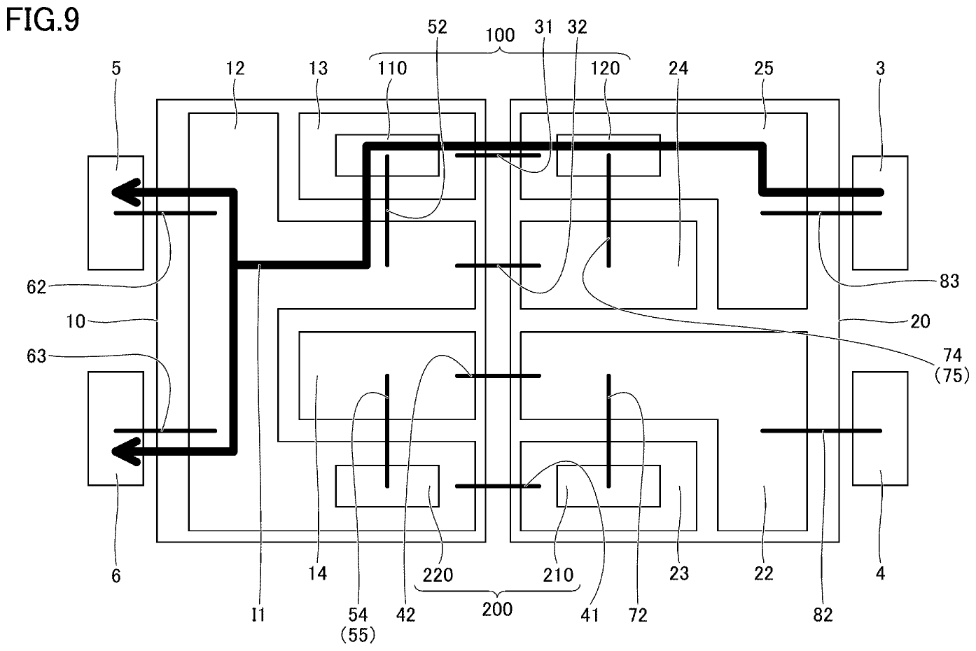

Next, an operation of the semiconductor device 1 according to the first embodiment will be described. FIGS. 9 to 12 are schematic views illustrating the operation of the semiconductor device according to the first embodiment.

FIG. 9 illustrates a path of the current I1 flowing from the P terminal 3 to the first O terminal 5 and the second O terminal 6. As illustrated in FIG. 9, the current I1 flows from the P terminal 3 to the first O terminal 5 and the second O terminal 6 via the wire 83, the conductive layer 25, the wire 31, the conductive layer 13, the first transistor group 110A, the wire 52, the conductive layer 12, and the wires 62 and 63.

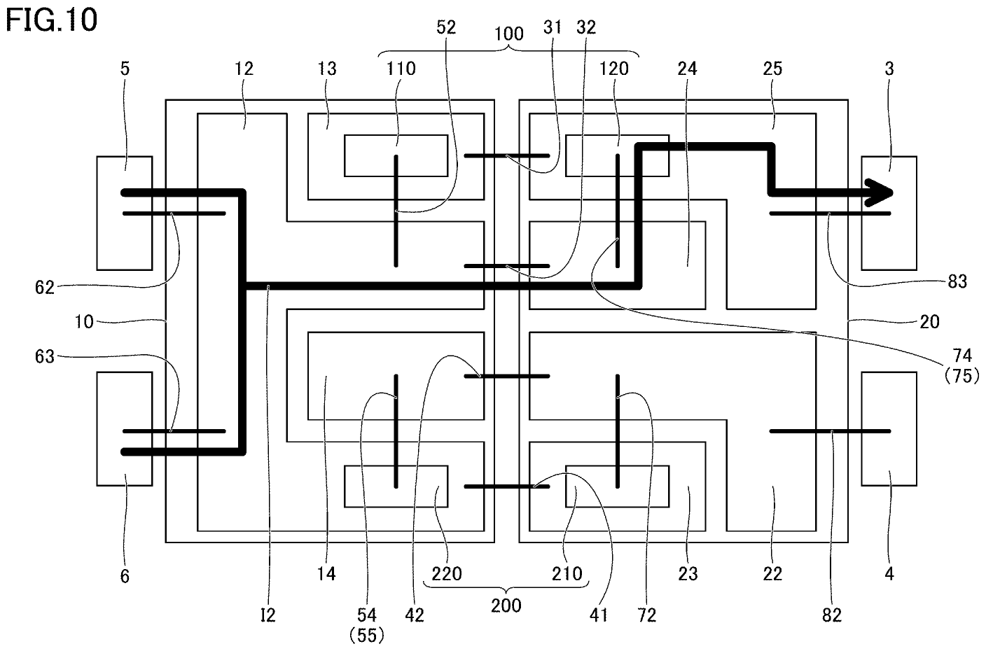

FIG. 10 illustrates a path of the current I2 flowing from the first O terminal 5 and the second O terminal 6 to the P terminal 3. As illustrated in FIG. 10, the current I2 flows from the first O terminal 5 and the second O terminal 6 to the P terminal 3 via the wires 62 and 63, the conductive layer 12, the wire 32, the conductive layer 24, the wires 74 and 75, the first diode group 120A, the conductive layer 25, and the wire 83.

As described above, the current I1 flowing from the P terminal 3 to the first O terminal 5 and the second O terminal 6 flows through the wire 31 but does not flow through the wire 32. With respect to the above, the current I2 flowing from the first O terminal 5 and the second O terminal 6 to the P terminal 3 flows through the wire 32, but does not flow through the wire 31.

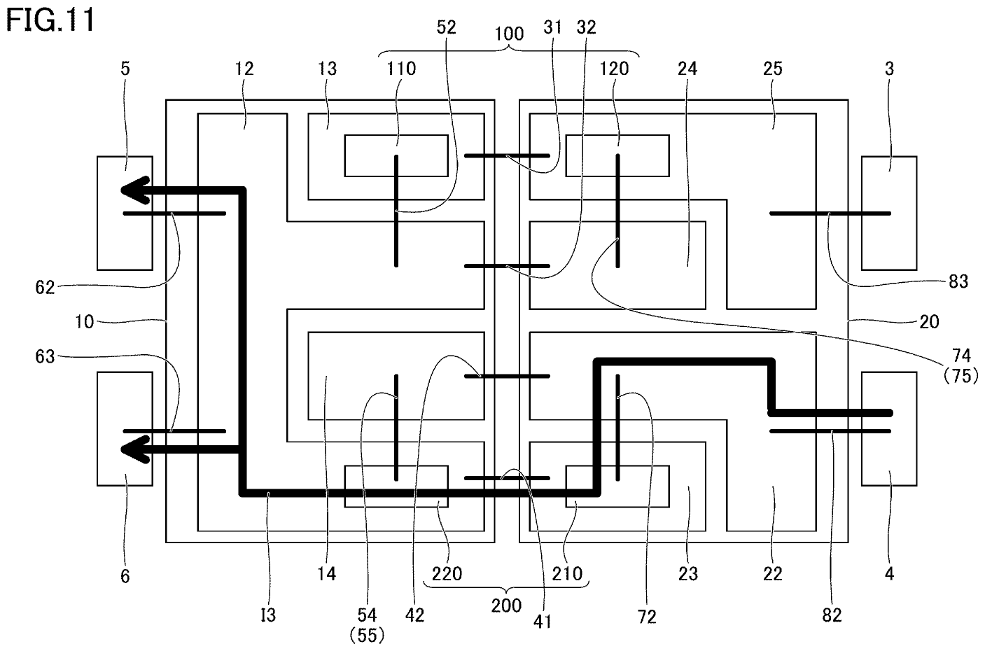

FIG. 11 illustrates a path of the current I3 flowing from the N terminal 4 to the first O terminal 5 and the second O terminal 6. As illustrated in FIG. 11, the current I3 flows from the N terminal 4 to the first O terminal 5 and the second O terminal 6 via the wire 82, the conductive layer 22, the wire 72, the second transistor group 210A, the conductive layer 23, the wire 41, the conductive layer 12, and the wires 62 and 63.

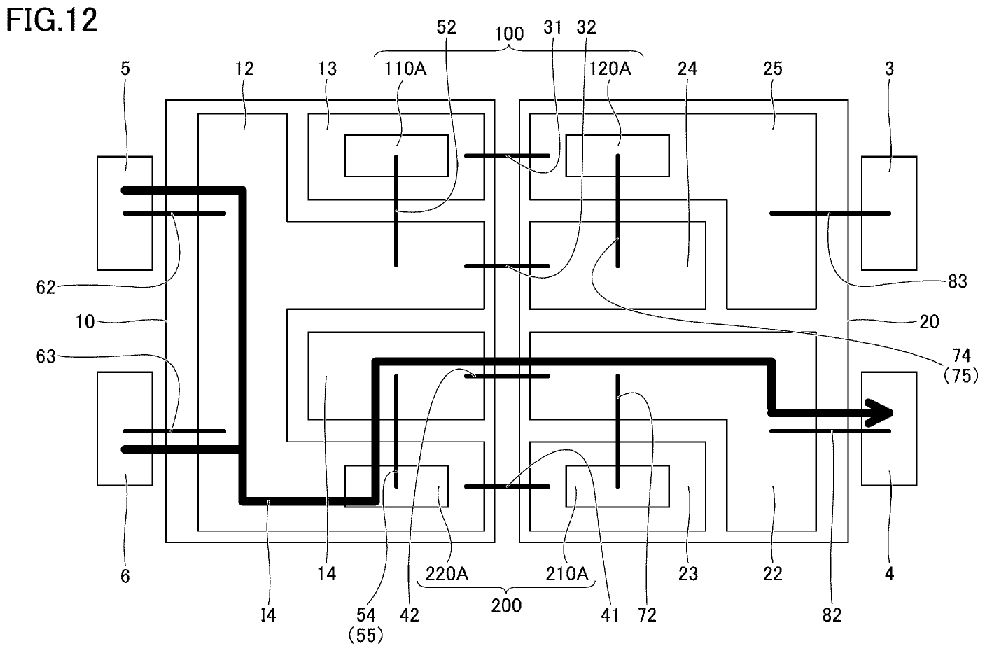

FIG. 12 illustrates a path of the current I4 flowing from the first O terminal 5 and the second O terminal 6 to the N terminal 4. As illustrated in FIG. 12, the current I4 flows from the first O terminal 5 and the second O terminal 6 to the N terminal 4 via the wires 62 and 63, the conductive layer 12, the second diode group 220A, the wires 54 and 55, the conductive layer 14, the wire 42, the conductive layer 22, and the wire 82.

As described above, the current I3 flowing from the N terminal 4 to the first O terminal 5 and the second O terminal 6 flows through the wire 41 but does not flow through the wire 42. With respect to the above, the current I4 flowing from the first O terminal 5 and the second O terminal 6 to the N terminal 4 flows through the wire 42 but does not flow through the wire 41.

In the semiconductor device 1 according to the first embodiment, the first transistor 110 and the first diode 120 are included in the upper arm 100, the first transistor 110 is provided on the first insulating substrate 10, and the first diode 120 is provided on the second insulating substrate 20. Thus, among the current I1 flowing from the P terminal 3 to the first O terminal 5 and the second O terminal 6 and the current I2 flowing from the first O terminal 5 and the second O terminal 6 to the P terminal 3, wires through which the current I1 and the current I2 pass are different in the wires 31 and 32. Therefore, the amount of heat generation in the wires 31 and 32 can be reduced in comparison with the case where the currents flowing between the first insulating substrate 10 and the second insulating substrate 20 pass through the same connection member.

Similarly, the second transistor 210 and the second diode 220 are included in the lower arm 200, and the second transistor 210 is provided on the second insulating substrate 20, and the second diode 220 is provided on the first insulating substrate 10. Thus, among the current I3 flowing from the N terminal 4 to the first O terminal 5 and the second O terminal 6 and the current I4 flowing from the first O terminal 5 and the second O terminal 6 to the N terminal 4, wires through which the current I3 and the current I4 pass are different in the wires 41 and 42. Therefore, the amount of heat generation in the wires 41 and 42 can be reduced in comparison with the case where the current flowing between the first insulating substrate 10 and the second insulating substrate 20 passes through the same connection member.

By reducing the amount of heat generation in such a way, the possibility that the amount of heat generation of the connection member and the wire becomes excessive can be suppressed, and the possibility that the wire becomes melted and cut can be reduced.

Because the wires 31, 32, 41, and 42 are used for the connection between the first insulating substrate 10 and the second insulating substrate 20, it is easy to connect the first insulating substrate 10 to the second insulating substrate 20. That is, it is easy to connect the conductive layer 13 to the conductive layer 25, it is easy to connect the conductive layer 12 to the conductive layer 24, it is easy to connect the conductive layer 14 to the conductive layer 22, and it is easy to connect the conductive layer 12 to the conductive layer 23. Instead of each of the wires 31, 32, 41, and 42, a metal plate such as a bus bar or the like may be used. In this case, a larger current easily flows.

Because the wire 52 is used for the connection between the first source electrode 112 and the conductive layer 12, and the wire 74 is used for the connection between the first anode electrode 121 and the conductive layer 24, it is easy to connect the first source electrode 112 to the conductive layer 12 and it is easy to connect the first anode electrode 121 to the conductive layer 24. Additionally, because the wire 72 is used for the connection between the second source electrode 212 and the conductive layer 22 and the wire 54 is used for the connection between the second anode electrode 221 and the conductive layer 14, it is easy to connect the second source electrode 212 to the conductive layer 22 and it is easy to connect the second anode electrode 221 to the conductive layer 14.

The multiple first transistors 110 are arranged adjacent to each other. The first source electrode 112 and the conductive layer 12 are directly connected by the wire 52, the first anode electrode 121 and the conductive layer 24 are connected by the wires 74 and 75, and the conductive layer 12 and the conductive layer 24 are electrically connected by the wire 31. Thus, the inductance of the power loop of each of the multiple first transistors 110 can be reduced, and the variation in the inductance of the power loop between the multiple first transistors 110 can be suppressed. Therefore, more stable operations of the multiple first transistors 110 can be achieved.

The multiple second transistors 210 are arranged adjacent to each other. The second source electrode 212 and the conductive layer 22 are directly connected by the wire 72, the second anode electrode 221 and the conductive layer 14 are connected by the wires 54 and 55, and the conductive layer 22 and the conductive layer 14 are electrically connected by the wire 42. Thus, the inductance of the power loop of each of the multiple second transistors 210 can be reduced, and the variation in the inductance of the power loop between the multiple second transistors 210 can be suppressed. Therefore, more stable operations of the multiple second transistors 210 can be achieved.

The first transistor 110 is disposed between the first gate terminal 131 and the second diode 220 in plan view. That is, the first transistor 110 of the upper arm 100 is disposed closer to the first gate terminal 131 than the second diode 220 of the lower arm 200. Additionally, the multiple first transistors 110 can be disposed in the vicinity of the conductive layer 11. Thus, it is easy to reduce the inductance of the gate loop of the first transistor 110. Additionally, the second transistor 210 is disposed between the second gate terminal 231 and the first diode 120 in plan view. That is, the second transistor 210 of the lower arm 200 is disposed closer to the second gate terminal 231 than the first diode 120 of the upper arm 100. Additionally, the multiple second transistors 210 can be disposed in the vicinity of the conductive layer 21. Thus, it is easy to reduce the inductance of the gate loop of the second transistor 210.

Further, the first gate electrodes 111 of the multiple first transistors 110 are connected to the first gate terminal 131, and the multiple first transistors 110 are disposed between the first gate terminal 131 and the second diode 220. Thus, it is easy to reduce the difference in the inductance of the gate loop between the multiple first transistors 110. Additionally, the second gate electrodes 211 of the multiple second transistors 210 are connected to the second gate terminal 231, and the multiple second transistors 210 are disposed between the second gate terminal 231 and the first diode 120. Thus, it is easy to reduce the difference in the inductance of the gate loop between the multiple second transistors 210.

The first transistor 110 and the second transistor 210 each may be a field effect transistor such as a metal-oxide-semiconductor (MOS) field effect transistor formed using silicon carbide, or the like. The first diode 120 and the second diode 220 each may be a Schottky barrier diode formed using silicon carbide. By using silicon carbide, excellent breakdown voltage can be obtained.

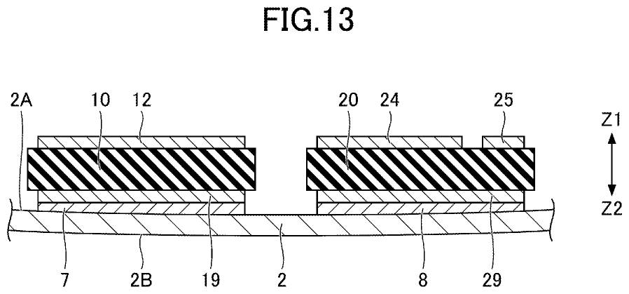

Here, as illustrated in FIG. 13, the second main surface 2B of the heat dissipation plate 2 is preferably curved in a convex shape. This is because good heat transfer efficiency can be easily obtained by bringing the heat dissipation plate 2 into close contact with a cooler or the like by using TIM or the like.

### Second Embodiment

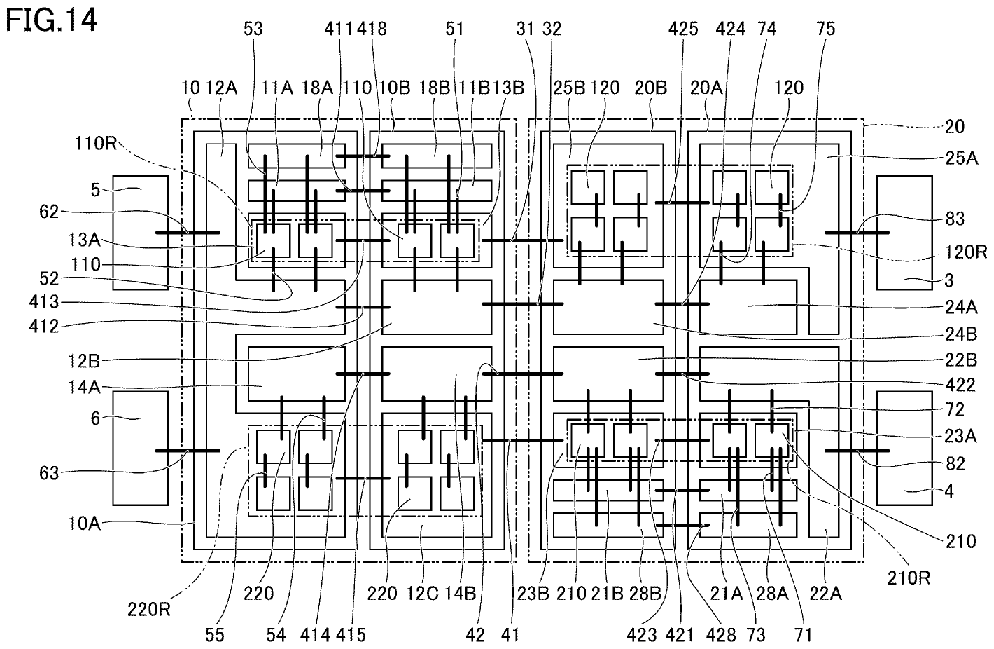

Next, a second embodiment will be described. FIG. 14 is a schematic view illustrating a configuration of a first insulating substrate and a second insulating substrate in a semiconductor device according to the second embodiment.

In the semiconductor device according to the second embodiment, as illustrated in FIG. 14, the first insulating substrate 10 includes a third insulating substrate 10A and a fourth insulating substrate 10B, and the second insulating substrate 20 includes a fifth insulating substrate 20A and a sixth insulating substrate 20B. The fourth insulating substrate 10B is disposed on the X1 side from the third insulating substrate 10A, and the sixth insulating substrate 20B is disposed on the X2 side from the fifth insulating substrate 20A.

The third insulating substrate 10A includes conductive layers 11A, 12A, 13A, 14A, and 18A on the Z1 side surface, and includes a conductive layer (not illustrated) on the Z2 side surface. The conductive layer provided on the Z2 side surface is bonded to the heat dissipation plate 2 by the bonding material 7 such as solder or the like, similarly as the conductive layer 19. Multiple first transistors 110, for example, two first transistors 110 are implemented on the conductive layer 13A. The two first transistors 110 are arranged in the X1-X2 direction. Multiple second diodes 220, for example, four second diodes 220 are implemented on the conductive layer 12A. The four second diodes 220 are arranged in two rows, two each in the X1-X2 direction.

The fourth insulating substrate 10B includes conductive layers 11B, 12B, 12C, 13B, 14B, and 18B on the Z1 side surface, and includes a conductive layer (not illustrated) on the Z2 side surface. The conductive layer provided on the Z2 side surface is bonded to the heat dissipation plate 2 by the bonding material 7 such as solder or the like, similarly as the conductive layer 19. Multiple first transistors 110, for example, two first transistors 110 are implemented on the conductive layer 13B. The two first transistors 110 are arranged in the X1-X2 direction. Multiple second diodes 220, for example, four second diodes 220 are implemented on the conductive layer 12C. The four second diodes 220 are arranged in two rows, two each in the X1-X2 direction.

Wire 411, wire 412, wire 413, wire 414, wire 415, and wire 418 are provided. The wire 411 connects the conductive layer 11A to the conductive layer 11B. The wire 412 connects the conductive layer 12A to the conductive layer 12B. The wire 413 connects the conductive layer 13A to the conductive layer 13B. The wire 414 connects the conductive layer 14A to the conductive layer 14B. The wire 415 connects the conductive layer 12A to the conductive layer 12C. The wire 418 connects the conductive layer 18A to the conductive layer 18B.

The conductive layers 11A and 11B are part of the conductive layer 11. The conductive layers 12A, 12B, and 12C are part of the conductive layer 12. The conductive layers 13A and 13B are part of the conductive layer 13. The conductive layers 14A and 14B are part of the conductive layer 14. The conductive lavers 18A and 18B are part of the conductive layer 18.

The fifth insulating substrate 20A includes conductive layers 21A, 22A, 23A, 24A, 25A, and 28A on the Z1 side surface, and includes a conductive layer (not illustrated) on the Z2 side surface. The conductive layer provided on the Z2 side surface is bonded to the heat dissipation plate 2 by the bonding material 8 such as solder or the like, similarly as the conductive layer 29. Multiple second transistors 210, for example, two second transistors 210 are implemented on the conductive layer 23A. The two second transistors 210 are arranged in the X1-X2 direction. Multiple first diodes 120, for example, four first diodes 120 are implemented on the conductive layer 25A. The four first diodes 120 are arranged in two rows, two each in the X1-X2 direction.

The sixth insulating substrate 20B includes conductive layers 21B, 22B, 23B, 24B, 25B, and 28B on the Z1 side surface, and includes a conductive layer (not illustrated) on the Z2 side surface. The conductive layer provided on the Z2 side surface is bonded to the heat dissipation plate 2 by the bonding material 8 such as solder or the like, similarly as the conductive layer 29. Multiple second transistors 210, for example, two second transistors 210 are implemented on the conductive layer 23B. The two second transistors 210 are arranged in the X1-X2 direction. Multiple first diodes 120, for example, four first diodes 120 are implemented on the conductive layer 25B. The four first diodes 120 are arranged in two rows, two each in the X1-X2 direction.

Wire 421, wire 422, wire 423, wire 424, wire 425, and wire 428 are provided. The wire 421 connects the conductive layer 21A to the conductive layer 21B. The wire 422 connects the conductive layer 22A to the conductive layer 22B. The wire 423 connects the conductive layer 23A to the conductive layer 23B. The wire 424 connects the conductive layer 24A to the conductive layer 24B. The wire 425 connects the conductive layer 25A to the conductive layer 25B. The wire 428 connects the conductive layer 28A to the conductive layer 28B.

The conductive layers 21A and 21B are part of the conductive layer 21. The conductive lavers 22A and 22B are part of the conductive layer 22. The conductive layers 23A and 23B are part of the conductive layer 23. The conductive layers 24A and 24B are part of the conductive layer 24. The conductive layers 25A and 25B are part of the conductive layer 25. The conductive layers 18A and 18B are part of the conductive layer 18.

The other configurations are substantially the same as those of the first embodiment.

According to the second embodiment, substantially the same effect as that of the first embodiment can also be obtained. Additionally, in the second embodiment, because the first insulating substrate 10 includes the third insulating substrate 10A and the fourth insulating substrate 10B, it is easy to bring the third insulating substrate 10A and the fourth insulating substrate 10B into closer contact with the first main surface 2A of the heat dissipation plate 2. Similarly, because the second insulating substrate 20 includes the fifth insulating substrate 20A and the sixth insulating substrate 20B, it is easy to bring the fifth insulating substrate 20A and the sixth insulating substrate 20B into closer contact with the first main surface 2A of the heat dissipation plate 2.

### Third Embodiment

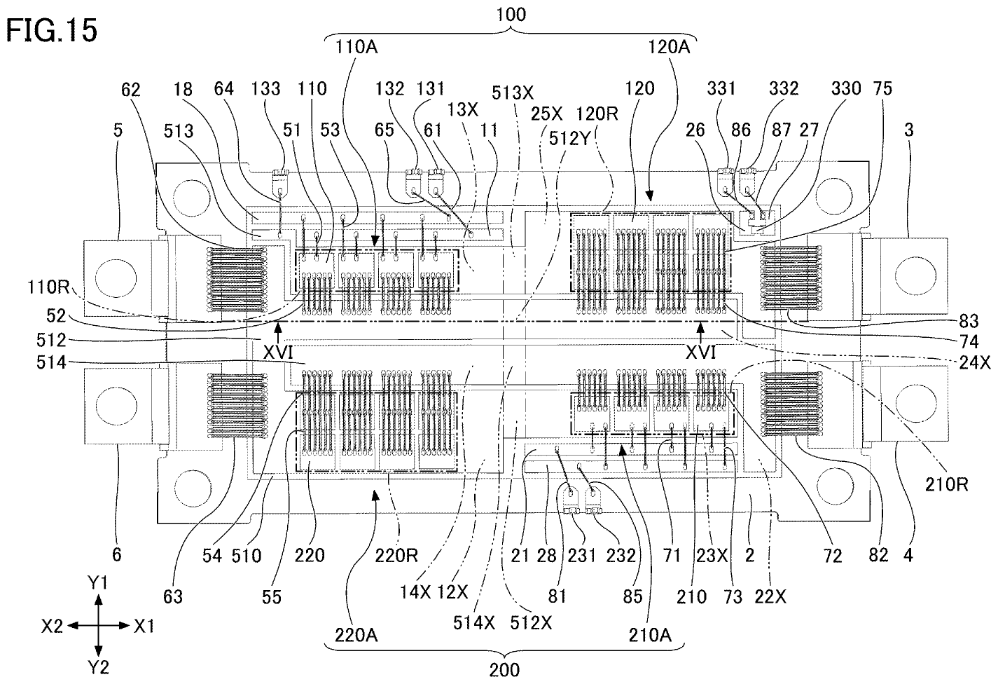

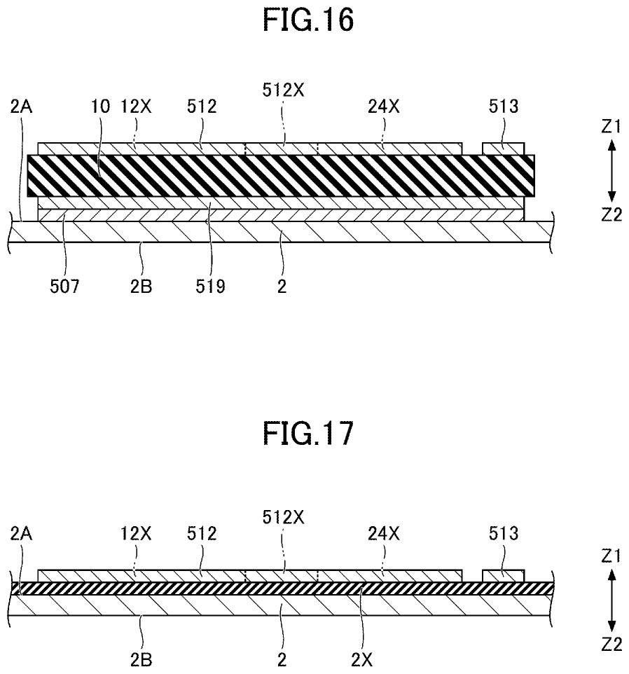

Next, a third embodiment will be described. FIG. 15 is a top view illustrating a semiconductor device according to the third embodiment. Here, as in FIG. 2, FIG. 15 is illustrated with seeing through the case. FIG. 16 is a cross-sectional view illustrating a relationship between a heat dissipation plate and an insulating substrate in the semiconductor device according to the third embodiment. FIG. 16 corresponds to a cross-sectional view taken along the line XVI-XVI in FIG. 15.

In the semiconductor device according to the third embodiment, as illustrated in FIG. 15 and FIG. 16, instead of the first insulating substrate 10 and the second insulating substrate 20, an insulating substrate 510 is disposed on the Z1 side of the heat dissipation plate 2. That is, the insulating substrate 510 is disposed on the first main surface 2A of the heat dissipation plate 2.

The insulating substrate 510 includes conductive layers 11, 512, 513, 514, 18, 21, 26, 27, and 28 on the Z1 side surface, and a conductive layer 519 on the Z2 side surface. The conductive layer 519 is bonded to the heat dissipation plate 2 by a bonding material 507 such as solder or the like.

The conductive layer 512 includes a region 12X corresponding to the conductive layer 12 in the first embodiment, a region 23X corresponding to the conductive layer 23, a region 24X corresponding to the conductive layer 24, a region 512X connecting the region 12X to the region 23X, and a region 512Y connecting the region 12X to the region 24X. Multiple second diodes 220, for example, eight second diodes 220 are implemented on the conductive layer 512, and multiple second transistors 210, for example, four second transistors 210 are implemented on the region 23X.

The conductive layer 513 includes a region 13X corresponding to the conductive layer 13 in the first embodiment, a region 25X corresponding to the conductive layer 25, and a region 513X connecting the region 13X to the region 25X. Multiple first transistors 110, for example, four first transistors 110 are implemented on the region 13X, and multiple first diodes 120, for example, eight first diodes 120 are implemented on the region 25X.

The conductive layer 514 includes a region 14X corresponding to the conductive layer 14 in the first embodiment, a region 22X corresponding to the conductive layer 22, and a region 514X connecting the region 14X to the region 22X.

The semiconductor device according to the third embodiment does not include the wire 31, the wire 32, the wire 41, and the wire 42.

A combination of the conductive layer 512, the wire 52, and the wires 74 and 75 is an example of a combination of the third conductive pattern, the first connection member, and the second connection member. The combination of the conductive layer 514, the wire 72, and the wires 54 and 55 is another example of the combination of the third conductive pattern, the first connection member, and the second connection member.

The other configurations are substantially the same as those of the first embodiment.

According to the third embodiment, substantially the same effect as that of the first embodiment can be obtained.

For example, the multiple first transistors 110 are arranged adjacent to each other. The first source electrode 112 and the conductive layer 512 are directly connected by the wire 52, and the first anode electrode 121 and the conductive layer 512 are connected by the wires 74 and 75. Thus, the inductance of the power loop of each of the multiple first transistors 110 can be reduced, and the variation in the inductance of the power loop between the multiple first transistors 110 can be suppressed. Therefore, more stable operations of the multiple first transistors 110 can be achieved.

Additionally, the multiple second transistors 210 are arranged adjacent to each other. The second source electrode 212 and the conductive layer 514 are directly connected by the wire 72, and the second anode electrode 221 and the conductive layer 514 are connected by the wires 54 and 55. Thus, the inductance of the power loop of each of the multiple second transistors 210 can be reduced, and the variation in the inductance of the power loop between the multiple second transistors 210 can be suppressed. Therefore, more stable operations of the multiple second transistors 210 can be achieved.

Here, the insulating substrate 510 may not be used in the third embodiment. FIG. 17 is a cross-sectional view illustrating a relationship between a heat dissipation plate and a conductive layer in a modified example of the third embodiment. FIG. 17 corresponds to a cross-sectional view taken along the line XVI-XVI in FIG. 15. For example, as illustrated in FIG. 17, an insulating layer 2X such as resin or the like may be provided on the heat dissipation plate 2, and the conductive layers 11, 512, 513, 514, 18, 21, 26, 27, and 28 may be provided on the insulating layer 2X.

In the present disclosure, the transistor is not limited to a MOS FET, and the transistor may be an insulated gate bipolar transistor (IGBT). When the transistor is an IGBT, the emitter electrode is an example of the first electrode.

Although the embodiments have been described in detail above, the embodiments are not limited to the specific embodiments, and various modifications and changes can be made within the scope described in the claims.

### DESCRIPTION OF THE REFERENCE NUMERALS

1: semiconductor device
2: heat dissipation plate
2A: first main surface
2B: second main surface
3: P terminal
4: N terminal
5: first O terminal
6: second O terminal
7, 8: bonding material
9: case
10: first insulating substrate
10A: third insulating substrate
10B: fourth insulating substrate
11, 11A, 11B, 12A, 12B, 12C, 13, 13A, 13B, 14A, 14B, 18, 18A, 18B, 19: conductive layer
12: conductive layer (first conductive pattern)
12X, 13X, 14X: region
14: conductive layer (second conductive pattern)
20: second insulating substrate
20A: fifth insulating substrate
20B: sixth insulating substrate
21, 21A, 21B, 22A, 22B, 23, 23A, 23B, 24A, 24B, 25, 25A, 25B, 26, 27, 28, 28A, 28B, 29: conductive layer
22X, 23X, 24X, 25X: region
22: conductive layer (first conductive pattern)
24: conductive layer (second conductive pattern)
31, 32: wire
41, 42: wire
51, 53: wire
52: wire (first connection member)
54, 55: wire (second connection member)
61, 62, 63, 64, 65: wire
71, 73: wire
72: wire (first connection member)
74, 75: wire (second connection member)
81, 82, 83, 85, 86, 87: wire
91, 92: side wall
93, 94: end wall
95, 96: terminal block
100: upper arm
110: first transistor
110A: first transistor group
110B: first transistor aggregation region
111: first gate electrode
112: first source electrode
113: first drain electrode
120: first diode
120A: first diode group
120R: first diode aggregation region
121: first anode electrode
122: first cathode electrode
131: first gate terminal
132: first sense source terminal
133: sense drain terminal
200: lower arm
210: second transistor
210A: second transistor group
210R: second transistor aggregation region
211: second gate electrode
212: second source electrode
213: second drain electrode
220: second diode
220A: second diode group
220R: second diode aggregation region
221: second anode electrode
222: second cathode electrode
231: second gate terminal
232: second sense source terminal
330: thermistor
331: first thermistor terminal
332: second thermistor terminal
411, 412, 413, 414, 415, 418: wire
421, 422, 423, 424, 425, 428: wire
507: bonding material
510: insulating substrate
512: conductive layer (third conductive pattern)
514: conductive layer (third conductive pattern)
513, 519: conductive layer
512X, 512Y, 513X, 514X: region
I1, I2, I3, I4: current

1. A semiconductor device comprising:
a plurality of transistors electrically connected to each other in parallel, the plurality of transistors respectively including first electrodes;
a diode electrically connected in parallel to the plurality of transistors, the diode including an anode electrode;
a first conductive pattern;
a second conductive pattern electrically connected to the first conductive pattern;
a plurality of first connection members directly connecting the first electrodes of the plurality of transistors to the first conductive pattern, respectively; and
a second connection member connecting the anode electrode to the second conductive pattern,
wherein each of the first electrodes is a source electrode or an emitter electrode, and
wherein the plurality of transistors are arranged adjacent to each other.

2. A semiconductor device comprising:
a plurality of transistors electrically connected to each other in parallel, the plurality of transistors respectively including first electrodes;
a diode electrically connected in parallel to the plurality of transistors, the diode including an anode electrode;
a third conductive pattern;
a plurality of first connection members directly connecting the first electrodes of the plurality of transistors to the third conductive pattern, respectively; and
a second connection member connecting the anode electrode to the third conductive pattern,
wherein each of the first electrodes is a source electrode or an emitter electrode, and
wherein the plurality of transistors are arranged adjacent to each other.

3. The semiconductor device as claimed in claim 1, wherein the plurality of transistors are aggregated in a first region having a rectangular shape.

4. The semiconductor device as claimed in claim 1, wherein the plurality of transistors are arranged side by side in a first direction.

5. The semiconductor device as claimed in claim 1, wherein the second connection member is independent of the plurality of first connection members.

6. The semiconductor device as claimed in claim 1, wherein the diode is not disposed between transistors adjacent to each other among the plurality of transistors.

7. The semiconductor device as claimed in claim 1, wherein each of the transistors is a field effect transistor formed using silicon carbide.

8. The semiconductor device as claimed in claim 1, wherein the diode is a Schottky barrier diode formed using silicon carbide.

9. The semiconductor device as claimed in claim 1, comprising:
a case accommodating the plurality of transistors and the diode; and
a control terminal attached to the case, the control terminal being connected to control electrodes of the plurality of transistors,
wherein the case has a pair of side walls opposite to each other, and a pair of end walls connecting both ends of the pair of side walls, and
wherein the control terminal is provided on a wall positioned closest to the plurality of transistors among the pair of side walls and the pair of end walls.

10. The semiconductor device as claimed in claim 2, wherein the plurality of transistors are aggregated in a first region having a rectangular shape.

11. The semiconductor device as claimed in claim 2, wherein the plurality of transistors are arranged side by side in a first direction.

12. The semiconductor device as claimed in claim 2, wherein the second connection member is independent of the plurality of first connection members.

13. The semiconductor device as claimed in claim 2, wherein the diode is not disposed between transistors adjacent to each other among the plurality of transistors.

14. The semiconductor device as claimed in claim 2, wherein each of the transistors is a field effect transistor formed using silicon carbide.

15. The semiconductor device as claimed in claim 2, wherein the diode is a Schottky barrier diode formed using silicon carbide.

16. The semiconductor device as claimed in claim 2, comprising:
a case accommodating the plurality of transistors and the diode; and
a control terminal attached to the case, the control terminal being connected to control electrodes of the plurality of transistors,
wherein the case has a pair of side walls opposite to each other, and a pair of end walls connecting both ends of the pair of side walls, and
wherein the control terminal is provided on a wall positioned closest to the plurality of transistors among the pair of side walls and the pair of end walls.
